(19) United States
(12) Patent Application Publication
(10) Pub. No.: US 2026/0165132 A1
(43) Pub. Date: Jun. 11, 2026

(54) SEMICONDUCTOR DEVICE AND METHOD OF FABRICATING THE SAME

(71) Applicant: Samsung Electronics Co., Ltd., Suwon-si (KR)

(72) Inventor: HYUNSOO CHUNG, Suwon-si (KR)

(21) Appl. No.: 19/256,789

(22) Filed: Jul. 1, 2025

(30) Foreign Application Priority Data
Dec. 10, 2024 (KR) 10-2024-0182875

(51) Int. Cl. H01L 23/427; H01L 21/48

(52) U.S. Cl. CPC H10W 40/73; H10W 40/037

(57) ABSTRACT

A semiconductor device may include a substrate and a heat-dissipation chamber on the substrate. The heat-dissipation chamber may include a connection layer on the substrate, a bump structure including a plurality of micro-bumps on the connection layer, and a channel structure on the connection layer. A chamber space enclosed by the connection layer and the channel structure is formed within the heat-dissipation chamber. The micro-bumps may be arranged to be spaced apart from each other along a top surface of the substrate.

### CROSS-REFERENCE TO RELATED APPLICATION

This U.S. non-provisional patent application claims priority under 35 U.S.C. § 119 to Korean Patent Application No. 10-2024-0182875, filed on Dec. 10, 2024, in the Korean Intellectual Property Office, the disclosure of which is incorporated by reference herein in its entirety.

### BACKGROUND

The present disclosure relates to an electronic device such as a semiconductor device

including a heat-dissipation device and a method of fabricating the same, more particularly, to the heat-dissipation device including a heat-dissipation chamber.

A semiconductor device may include the heat-dissipation device and an integrated circuit chip, and may be designed to facilitate the function of the integrated circuit chip as a component in an electronic product. The semiconductor device may be a semiconductor package. In general, the semiconductor package includes a printed circuit board (PCB) and a semiconductor chip. The semiconductor chip may be mounted on the PCB and electrically connected to the PCB by bonding wires or bumps. With recent advancements in the electronics industry, semiconductor package technology is evolving in various ways to achieve miniaturization, weight reduction, and lower manufacturing costs. Furthermore, as the application of this technology expands into various fields, including mass storage devices, diverse types of semiconductor packages are emerging. In particular, as the semiconductor device demands more electric power for higher speed and larger capacity, the thermal characteristics of the semiconductor package become increasingly important.

### SUMMARY

An embodiment of the inventive concept provides a semiconductor package with an improved heat-dissipation property.

According to an embodiment of the inventive concept, a semiconductor device includes a substrate and a heat-dissipation chamber on the substrate, wherein the heat-dissipation chamber includes a connection layer on the substrate, a bump structure including a plurality of micro-bumps on the connection layer, the micro-bumps being arranged to be spaced apart from each other on the connection layer and extending upward from the connection layer, and a channel structure on the connection layer, wherein a chamber space enclosed by the connection layer and the channel structure is formed within the heat-dissipation chamber.

According to an embodiment of the inventive concept, a semiconductor device includes a substrate, and a heat-dissipation chamber on the substrate, wherein the heat-dissipation chamber includes a bump structure including a plurality of micro-bumps which are arranged to be spaced apart from each other along a top surface of the substrate, and a channel structure on the substrate, the channel structure comprising a side channel portion which extends upward in a third direction perpendicular to the top surface of the substrate, and an upper channel portion which covers an area surrounded by top portions of the side channel portion, wherein a chamber space enclosed by the channel structure is formed within the heat-dissipation chamber.

According to an embodiment of the inventive concept, a semiconductor device includes a lower substrate, an interposer substrate on the lower substrate, a chip structure provided on the interposer substrate, a heat-dissipation chamber adjacent to the chip structure, a heat spreader covering the heat-dissipation chamber, and the chip structure, wherein the heat-dissipation chamber includes a connection layer on the interposer substrate, a bump structure including a plurality of micro-bumps on the connection layer, the plurality of micro-bumps being arranged to be spaced apart from each other along the interposer substrate, and a channel structure on the connection layer, wherein a chamber space enclosed by the connection layer and the channel structure is formed within the heat-dissipation chamber.

### BRIEF DESCRIPTION OF THE DRAWINGS

FIG. 1 is a plan view illustrating a heat-dissipation device according to an embodiment

of the inventive concept.

FIG. 2A is a cross-sectional view taken along a line A-A′ of FIG. 1 to illustrate a heat-dissipation device according to an embodiment of the inventive concept.

FIG. 2B is a cross-sectional view illustrating a heat-dissipation device according to an embodiment of the inventive concept and corresponding to the line A-A′ of FIG. 1.

FIG. 3 is an enlarged perspective view illustrating a portion ‘Q’ of FIG. 1.

FIG. 4 is a cross-sectional view illustrating a semiconductor package including a heat-dissipation device, according to an embodiment of the inventive concepts.

FIGS. 5 to 8 are cross-sectional views illustrating a method of fabricating a heat-dissipation device, according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their description will be omitted.

Spatially relative terms, such as “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Items described in the singular herein may be provided in plural, as can be seen, for example, in the drawings. Thus, the description of a single item that is provided in plural should be understood to be applicable to the remaining plurality of items unless context indicates otherwise. The term “include” mean that only the listed element or material exists, or other elements or materials may exist.

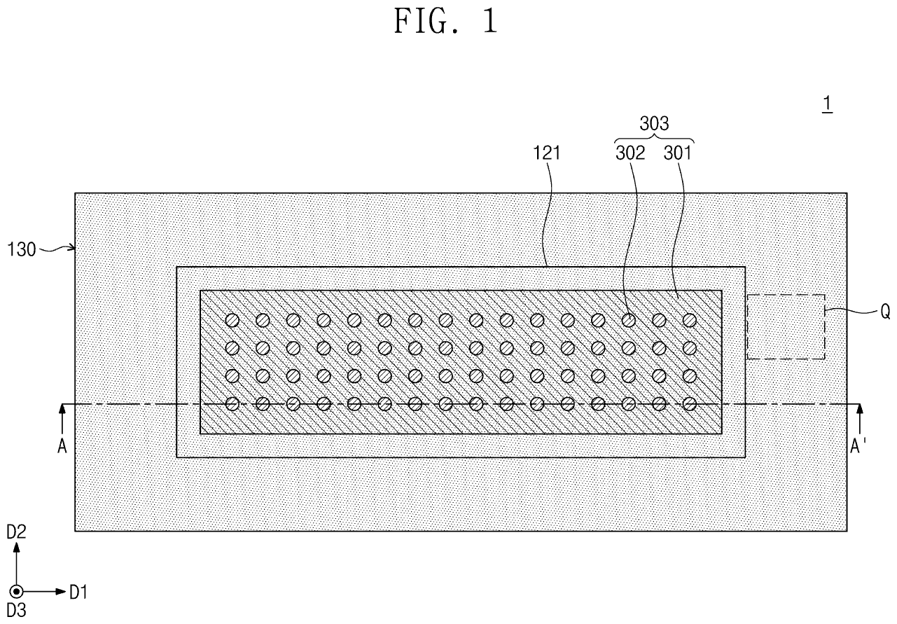

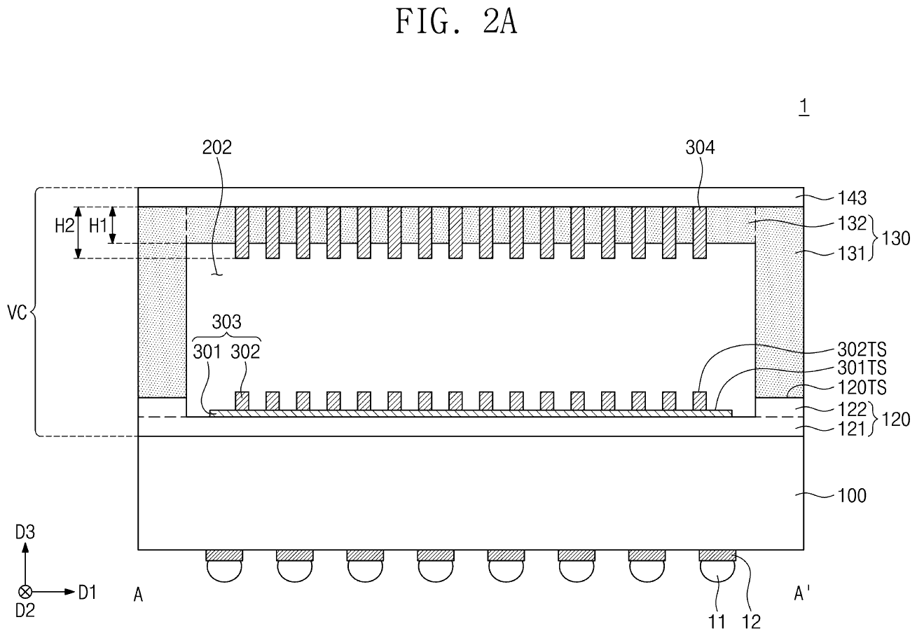

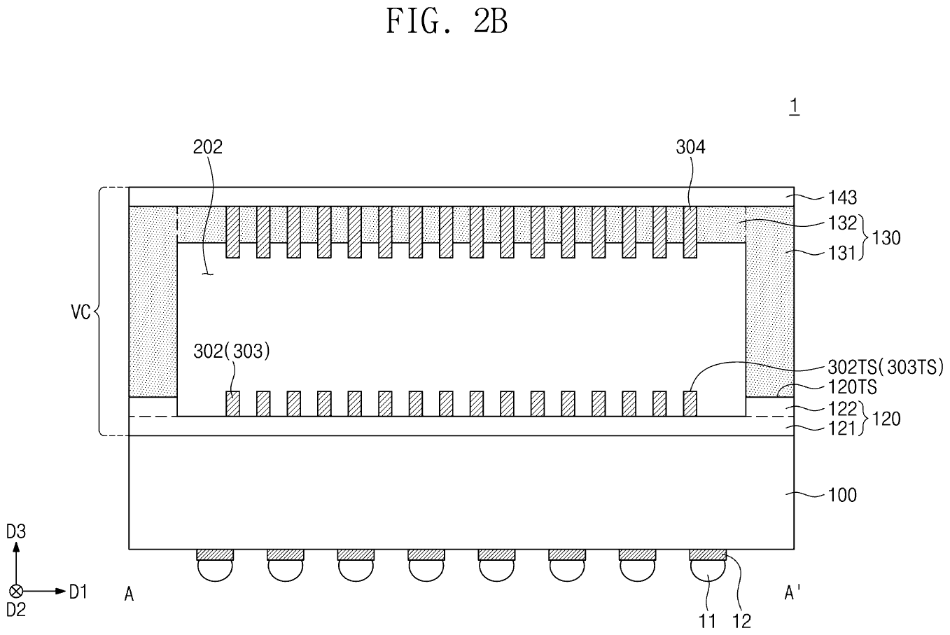

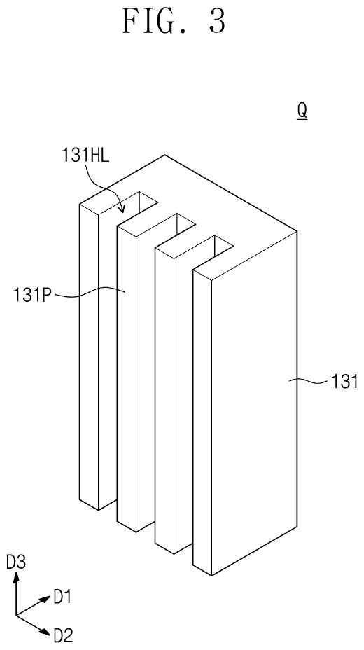

FIG. 1 is a plan view illustrating a semiconductor device according to an embodiment of the inventive concept. FIG. 2A is a cross-sectional view taken along a line A-A′ of FIG. 1 to illustrate the heat-dissipation device according to an embodiment of the inventive concept. FIG. 3 is an enlarged perspective view illustrating a portion ‘Q’ of FIG. 1. The heat-dissipation device may be a heat-dissipation chamber VC.

Referring to FIGS. 1, 2A, and 3, The semiconductor device 1 may include a heat-dissipation device. The semiconductor device 1 may emit heat, which is generated therein, to the outside. The semiconductor device 1 may include a substrate 100, a solder pad 12 on a surface of the substrate 100, a solder ball 11 connected to the solder pad 12, and a heat-dissipation chamber VC on the substrate 100. The substrate 100 may be a semiconductor chip such as GPU, CPU, or application-specific integrated circuit (ASIC).

The substrate 100 may be a plate-shaped structure extending in a first direction D1 and a second direction D2. The first and second directions D1 and D2 may not be the same direction. For example, the first and second directions D1 and D2 may be horizontal directions that are orthogonal to each other. The substrate 100 may be, for example, a silicon substrate. Alternatively, the substrate 100 may include a redistribution substrate or a printed circuit board. For example, the substrate 100 may be a semiconductor chip such as GPU, CPU, or application-specific integrated circuit (ASIC), or may be such a chip formed on a redistribution substrate or circuit board.

The solder pad 12 may include a conductive material. For example, the solder pad 12 may be formed of or include copper (Cu).

The solder ball 11 may be formed on the solder pad 12. The semiconductor device 1 may be electrically connected to an external device through the solder ball 11. The solder ball 11 may include a solder material. The solder material may include a conductive material. For example, the solder material may be formed of or include at least one of tin, bismuth, lead, silver, or alloys thereof.

The semiconductor device 1 includes the heat-dissipation chamber VC which is formed with a connection layer 120 on the substrate 100, and a channel structure 130 on the connection layer 120. A chamber space 202 enclosed by the channel structure 130 and the connection layer 120 may be formed. The channel structure may include a penetration via 304 partially protruding into the chamber space 202. A bump structure 303 may be disposed on the connection layer 120. A passivation layer 143 may be formed on the channel structure 130.

In a plan view, the bump structure 303 and the penetration via 304 may be vertically overlapped with each other (e.g., may overlap along a vertical direction when viewed from a top-down view). The bump structure 303 may be entirely overlapped by the channel structure 130.

The connection layer 120 may be formed of an insulating material. The connection layer 120 may include a lower connection layer 121 and an upper connection layer 122 on the lower connection layer 121. The lower connection layer 121 may be a plate-shaped structure that extends in the first and second directions D1 and D2. The upper connection layer 122 may be a protruding shape which extends upward from an edge portion of the lower connection layer 121 in a third direction D3 perpendicular to a top surface of the substrate 100.

The edge of the upper connection layer 122 may be aligned with the edge of the lower connection layer 121. According to an embodiment, the upper connection layer 122 may include several portions which are separated from one other. The edge of each portion is aligned with the edge of the lower connection layer 121. For example, in a cross-sectional view, the upper connection layer 122 may include two portions which are separated from each other in the first direction D1. The lower and upper connection layers 121 and 122 may be directly connected with no intervening material between them. The lower and upper connection layers 121 and 122 may be formed of the same material.

The bump structure 303 may be formed on the lower connection layer 121. In a cross-sectional view, the bump structure 303 may be positioned between the portions of the upper connection layer 122. The bump structure 303 and the upper connection layer 122 may be spaced apart from each other in the first and second directions D1 and D2. The bump structure 303 may be formed on the lower connection layer 121, and the upper connection layer 122 may be formed on the lower connection layer 121 to enclose the bump structure 303. The upper connection layer 122 may define a boundary of a top surface of the lower connection layer 121 on which the bump structure 303 is formed. The top surface of the lower connection layer 121 may indicate a topmost surface of the lower connection layer 121.

The bump structure 303 may include a transfer layer 301 and a plurality of micro-bumps 302 on the transfer layer 301.

The transfer layer 301 may be a plate-shaped structure extending in the first and second directions D1 and D2. In a plan view, an area of the transfer layer 301 may be smaller than an area of the lower connection layer 121. The transfer layer 301 may include a conductive material. For example, the transfer layer 301 may be formed of or include copper.

The micro-bumps 302 may be provided on the transfer layer 301. The micro-bumps 302 may be arranged to be spaced apart from each other in the first and second directions D1 and D2. The micro-bumps 302 may include a conductive material. For example, the micro-bumps 302 may be formed of or include copper.

A level of a top surface 301TS of the transfer layer 301 may be lower than a level of a top surface 120TS of the upper connection layer 122. A level of a top surface 302TS of the micro-bumps 302 may be higher than a level of the top surface 120TS of the upper connection layer 122.

The channel structure 130 may include a side channel portion 131 which extends upward from the top surface of the substrate 100 or in the third direction D3, and an upper channel portion 132 which covers an area surrounded by top portions of the side channel portion 131.

The side channel portion 131 may include first to fourth side portions, in which the first and third portions are facing each other in the first direction D1, and the second and fourth portions are facing each other in the second direction D2. Each of first to fourth side portions may have the shape of a rectangular column with protrusions on one side. The side channel portion 131 may be formed on the upper connection layer 122. The upper connection layer 122 and the side channel portion 131 may overlap with each other in the third direction D3. The upper connection layer 122 may be disposed between the lower connection layer 121 and the side channel portion 131. The upper connection layer 122 may protrude from the lower connection layer 121 toward the side channel portion 131.

A level of the bottom surface of the side channel portion 131 may be higher than the level of the top surface 301TS of the transfer layer 301 and may be lower than the level of the top surface 302TS of the micro-bump 302.

The upper channel portion 132 may overlap with the bump structure 303 in the third direction D3. The upper channel portion 132 may overlap with the lower connection layer 121 in the third direction D3.

Referring to FIG. 3, the channel structure 130 may include a slot 131HL that is defined as a space, which extends vertically along inner surface of the side channel portion 131. The slot 131HL may have a dented rectangular shape extending in the third direction D3, but the inventive concept is not limited to this example. The channel structure 130 may include a protruding pattern 131P that is defined as a protrusion which protrudes horizontally and extends vertically along inner surface of the side channel portion 131. The protruding pattern 131P may have a rectangular shape protruding outward from the inner surface of the side channel portion 131, but the inventive concept is not limited to this example.

The passivation layer 143 may be formed on the channel structure 130. The passivation layer 143 may include an insulating material. The passivation layer 143 may be vertically overlapped with the connection layer 120. The passivation layer 143 may cover a top surface of the penetration via 304.

The chamber space 202, which is enclosed by the connection layer 120 and the channel structure 130, may refer to a space enclosed by the heat-dissipation chamber VC. More specifically, an empty space in the heat-dissipation chamber VC may be defined as the chamber space 202.

More specifically, the chamber space 202 may be a space enclosed by the exposed top surface of the lower connection layer 121, the exposed top surface of the bump structure 303, the exposed side surface of the upper connection layer 122, the exposed side surface of the side channel portion 131, and the exposed bottom surface of the upper channel portion 132.

The chamber space 202 may be enclosed by the side channel portion 131, the upper channel portion 132 and the connection layer 120. The protruding pattern 131P on inner surface of the side channel portion 131 may be exposed to the chamber space 202. A penetration via 304 may be exposed to the chamber space 202 at inner surface of the upper channel portion 132. The bump structure 303 may be exposed to the chamber space 202 to transfer heat outside the heat-dissipation chamber VC.

The chamber space 202 may be disconnected and sealed from an outer space. Vapor may be present in the chamber space 202. The vapor in the chamber space 202 may be water vapor (H₂O).

The penetration via 304 may include a portion partially protruding into the chamber space 202. The penetration via 304 may be a pillar-shaped structure which penetrates the upper channel portion 132 and protrudes partially into the chamber space 202. The penetration via 304 may include a conductive material. For example, the penetration via 304 may be formed of or include copper. The penetration via 304 and the bump structure 303 may be vertically spaced apart from each other. A length of the penetration vias 304 (i.e., H2) may be greater than a thickness of the upper channel portion 132 (i.e., H1) as shown in FIG. 2A.

According an embodiment, the heat-dissipation chamber VC of the semiconductor device 1 may include the bump structure 303 in a lower region of the heat-dissipation chamber VC, the penetration vias 304 in an upper region of the heat-dissipation chamber VC, and the channel structures 130. While the semiconductor chips of the semiconductor package perform high-speed operation, heat may be generated by the semiconductor device 1. The heat may be easily transmitted to the penetration vias 304 and emitted outside through the heat spreader 701 and through the channel structure 130.

FIG. 2B is a cross-sectional view illustrating a semiconductor device according to an embodiment of the inventive concept and corresponding to the line A-A′ of FIG. 1. Referring to FIG. 2B, the heat-dissipation device 1 according to an embodiment of the inventive concept is illustrated. Different features from an embodiment described with reference to the FIGS. 1, 2A, and 3, will be described below.

The bump structure 303 may include a plurality of micro-bumps 302 which are spaced apart from each other. For example, the bump structure 303 may include the micro-bumps 302, which are spaced apart from each other, and may not include the transfer layer 301 shown in FIG. 2A. Accordingly, bottom surfaces of the micro-bumps 302 may be in contact with the lower connection layer 121.

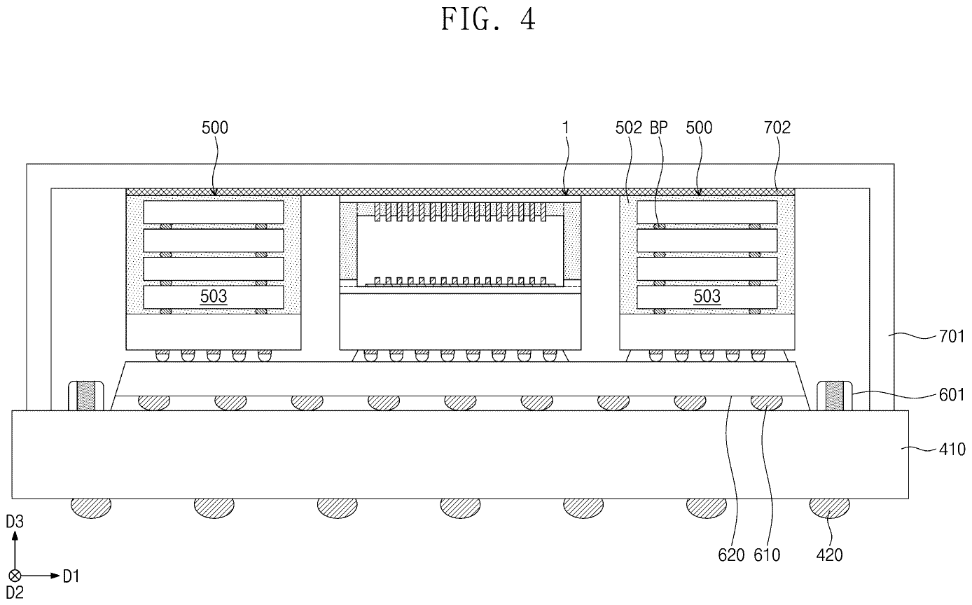

FIG. 4 is a cross-sectional view illustrating a semiconductor package including a semiconductor device, according to an embodiment of the inventive concept.

Referring to FIG. 4, the semiconductor package may include a lower substrate 410. The semiconductor package may further include first terminals 420 which are electrically connected to the lower substrate 410. The semiconductor package may be mounted on an external device (e.g., a main board) through the first terminals 420. The lower substrate 410 may include a semiconductor material. The first terminals 420 may include a conductive material.

An interposer substrate 620 may be disposed on the lower substrate 410. Second terminals 610 may be formed on bottom surface of the interposer substrate 620 to electrically connect the lower substrate 410 to the interposer substrate 620. The second terminals 610 may be disposed between the lower substrate 410 and the interposer substrate 620.

Passive devices 601 may be disposed on the lower substrate 410, and adjacent to the interposer substrate 620. For example, the passive devices 601 may be a capacitor.

One or more chip structures 500 may be disposed on the interposer substrate 620. The heat-dissipation device 1 described with reference to FIGS. 1 to 4 may be disposed between the chip structures 500.

The chip structure 500 may include a plurality of semiconductor chips 503 which are vertically stacked, a plurality of bumps BP which are disposed between the semiconductor chips 503, and a chip mold layer 502 enclosing the semiconductor chips 503 and the bumps BP. The semiconductor chips 503 may be memory chips or may be processing chips such as a graphics processing device (GPU) or a central processing device (CPU). Alternatively, the semiconductor chips 503 may include memory chips and a logic chip, in which memory chips and a logic chip are electrically connected with through-silicon vias (TSVs). A graphics processing device (GPU) or a central processing device (CPU) may be disposed adjacent to the chip structure 500 in the semiconductor package. The chip structure 500 and the GPU/CPU may be electrically connected through redistribution signal lines formed on the interposer substrate 620. Alternatively, the graphics processing device (GPU) or the central processing device (CPU) may be disposed under the heat-dissipation device so that the heat-dissipation device effectively emits out the heat generated in the graphics processing device (GPU) or the central processing device (CPU). The chip structure 500 may be a high bandwidth memory (HBM) which includes stacked DRAM chips over a logic chip. The DRAM chips and the logic chip are electrically connected by TSVs. The HBM may be disposed adjacent to GPU and electrically connected by redistribution signals on the interposer substrate 620.

The semiconductor device 1 may be disposed between the chip structures 500 which are spaced apart from each other, or the semiconductor device 1 may be disposed adjacent to the chip structure 500. The semiconductor device 1 may be connected to the lower substrate 410 through the interposer substrate 620, and may exhaust heat generated from the substrate 100 and the interposer substrate 620.

An adhesive layer 702 may be formed on the chip structures 500 and the semiconductor device 1. The adhesive layer 702 may cover the chip structures 500 spaced apart from each other and the semiconductor device 1 placed between the chip structures 500. A heat spreader 701 may be disposed in contact with the adhesive layer 702. The heat spreader 701 may cover the chip structures 500 and the semiconductor device 1 (e.g., the heat-dissipation device). The heat spreader 701 may transfer the heat generated in the chip structure outside. The heat spreader 701 may be disposed on the lower substrate 410.

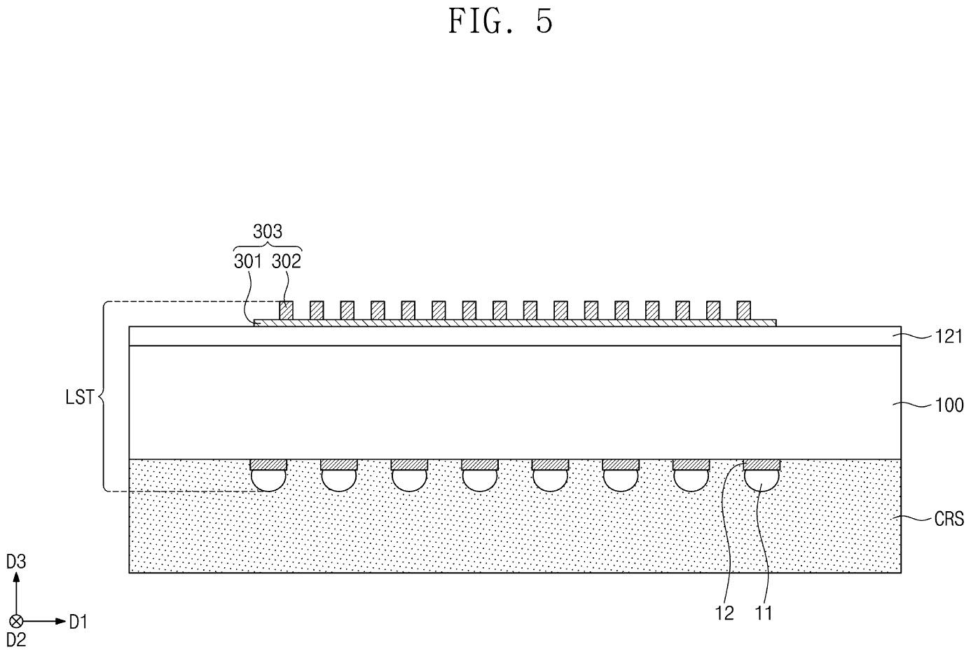

FIGS. 5 to 8 are cross-sectional views illustrating a method of fabricating a semiconductor package, according to an embodiment of the inventive concept.

Referring to FIG. 5, a lower structure LST may be provided on a carrier substrate CRS. The lower structure LST may be placed on and attached to the carrier substrate CRS. The lower structure LST may include the substrate 100, the solder pad 12 on bottom side of the substrate 100, the solder ball 11 on the solder pad 12, the lower connection layer 121 on the top side of the substrate 100, and the bump structure 303 on the lower connection layer 121. The forming the bump structure 303 may include griding the top surface of the lower connection layer 121 for flattening the top surface, and forming the transfer layer 301 and the micro-bumps 302 on the flattened top surface. The lower connection layer 121 may have a flat top surface. The bump structure 303 may be placed within the area of the lower connection layer 121.

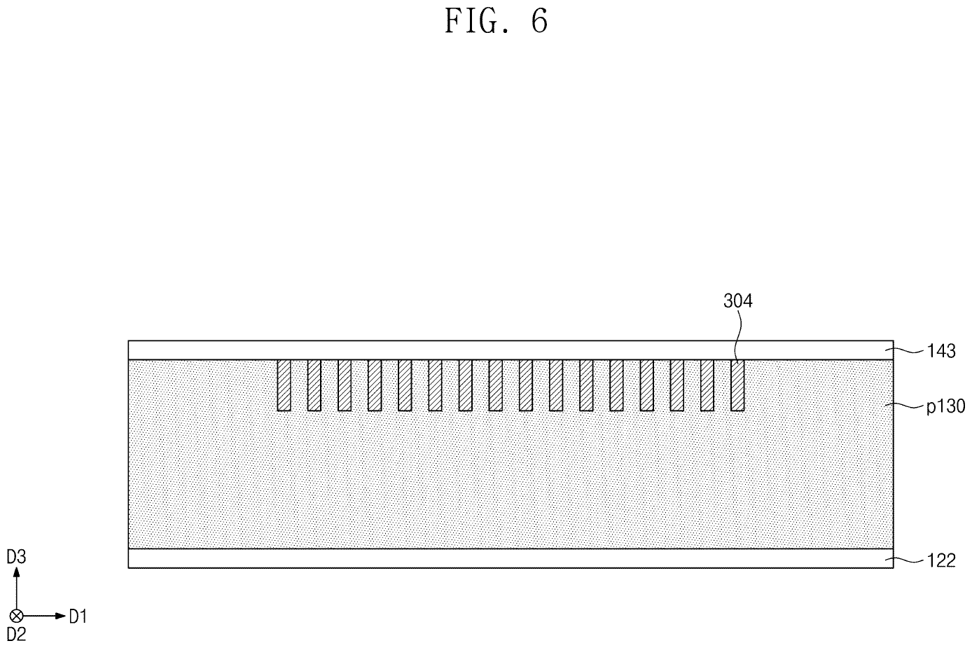

Referring to FIG. 6, the upper connection layer 122 may be formed on bottom side of a preliminary channel structure p130. The penetration vias 304 may be formed in a form of a pillar inserted in top surface of the preliminary channel structure p130 and extended downward from the top surface of the preliminary channel structure p130. The passivation layer 143 may be formed to cover top surfaces of the penetration vias 304 and the preliminary channel structure p130. The forming the penetration vias 304 may include forming a plurality of cavities in the preliminary channel structure p130, and filling the cavities with a conductive material.

After the formation of the penetration vias 304, a grinding process may be performed on top surfaces of the penetration vias 304 and a top surface of the preliminary channel structure p130 for flattening the top surfaces of the penetration vias 304 and a top surface of the preliminary channel structure p130. The passivation layer 143 may be formed on the flattened top surfaces of the penetration vias 304 and flattened top surface of the preliminary channel structure p130.

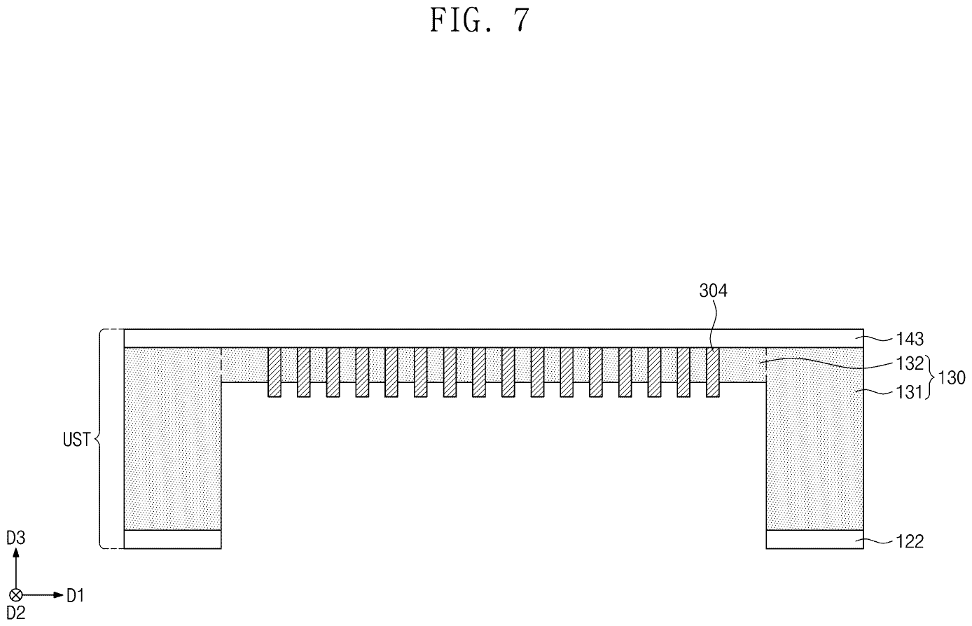

Referring to FIG. 7, a bottom portion of the preliminary channel structure p130 may be removed to expose bottom portions of the penetration vias 304. The partial removal of the preliminary channel structure p130 may be performed in the region including the penetration vias 304, preserving an edge portion of the preliminary channel structure p130. The preliminary channel structure p130 may be changed to a structure with a cavity in which bottom portions of the penetration vias 304 are exposed. A portion of the upper connection layer 122 corresponding to the cavity may also be removed (e.g., by the width of the cavity). The changed structure of the preliminary channel structure p130 may be an upper structure UST. The partial removal of the preliminary channel structure p130 may be performed to expose bottom surfaces of the penetration vias 304 and portions of side surfaces of the penetration vias 304.

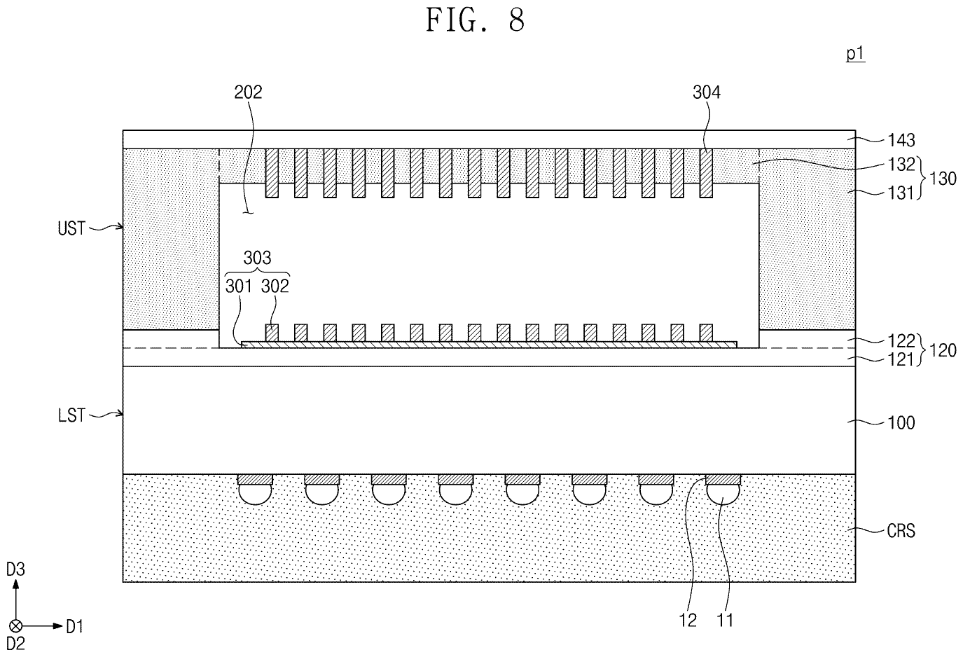

Referring to FIG. 8, the upper structure UST of FIG. 7 may be attached to the lower structure LST of FIG. 5. The lower connection layer 121 of the lower structure LST may include the same material as the upper connection layer 122 of the upper structure UST. Since the lower connection layer 121 of the lower structure LST and the upper connection layer 122 of the upper structure UST include the same material, they may be directly bonded to each other without an additional adhesion material interposed therebetween. Accordingly, there may be no visible interface between the lower and upper connection layers 121 and 122. The lower connection layer 121 and the upper connection layer 122 bonded together to form a preliminary semiconductor device p1.

Referring to FIGS. 8 and 2A, the carrier substrate CRS below the lower structure LST may be removed to expose the solder pad 12 and the solder ball 11, thereby achieving the semiconductor device 1 shown in FIG. 2A.

According to an embodiment of the inventive concept, a semiconductor device may include a heat-dissipation chamber which exhausts heat generated from the semiconductor device.

According to an embodiment of the inventive concept, the heat-dissipation chamber may include micro-bumps and penetration vias which effectively exhaust heat generated from the semiconductor chips of the chip structures.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a substrate; and
a heat-dissipation chamber on the substrate,
wherein the heat-dissipation chamber comprises:
a connection layer on the substrate;
a bump structure including a plurality of micro-bumps on the connection layer, the micro-bumps being arranged to be spaced apart from each other on the connection layer and extending upward from the connection layer; and
a channel structure on the connection layer,
wherein a chamber space enclosed by the connection layer and the channel structure is formed within the heat-dissipation chamber.

2. The semiconductor device of claim 1, wherein the channel structure comprises:
a side channel portion extending in a direction perpendicular to a top surface of the connection layer; and
an upper channel portion covering an area surrounded by top portions of the side channel portion,
wherein the side channel portion includes a protruding pattern on inner surface of the side channel portion which protrudes horizontally and extends upward from the top surface of the connection layer.

3. The semiconductor device of claim 2, wherein the heat-dissipation chamber includes a plurality of penetration vias penetrating the upper channel portion and protruding into the chamber space.

4. The semiconductor device of claim 3, wherein a length of each of the penetration vias is greater than a thickness of the upper channel portion.

5. The semiconductor device of claim 1, wherein the heat-dissipation chamber comprises a passivation layer on the channel structure.

6. The semiconductor device of claim 1, wherein the bump structure further comprises a transfer layer between the connection layer and the micro-bumps, in which the transfer layer is a plate-shaped structure which extends along a top surface of the substrate.

7. The semiconductor device of claim 6, wherein a level of a top surface of the transfer layer is lower than a level of a top surface of the connection layer.

8. The semiconductor device of claim 1, wherein a level of top surfaces of the micro-bumps is higher than a level of a top surface of the connection layer.

9. The semiconductor device of claim 1, wherein the substrate is one of GPU, CPU or ASIC, and heat generated from the substrate is emitted out through the heat-dissipation chamber.

10. A semiconductor device, comprising:
a substrate; and
a heat-dissipation chamber on the substrate,
wherein the heat-dissipation chamber comprises:
a bump structure including a plurality of micro-bumps which are arranged to be spaced apart from each other along a top surface of the substrate; and
a channel structure on the substrate, the channel structure comprising a side channel portion which extends upward in a third direction perpendicular to the top surface of the substrate, and an upper channel portion which covers an area surrounded by top portions of the side channel portion,
wherein a chamber space enclosed by the channel structure is formed within the heat-dissipation chamber.

11. The semiconductor device of claim 10, wherein the channel structure comprises a protruding pattern on inner surface of the side channel portion which protrudes horizontally and extends upward in a direction perpendicular to the top surface of the substrate.

12. The semiconductor device of claim 10, wherein the heat-dissipation chamber comprises a plurality of penetration vias penetrating the upper channel portion and protruding into the chamber space.

13. The semiconductor device of claim 12, wherein a length of each of the penetration vias is greater than a thickness of the upper channel portion.

14. The semiconductor device of claim 10, wherein the bump structure further comprises a transfer layer below the micro-bumps, in which the transfer layer is a plate-shaped structure which extends along the top surface of the substrate.

15. The semiconductor device of claim 14, wherein a level of a bottom surface of the side channel portion is higher than a level of a top surface of the transfer layer, and is lower than a level of a top surface of the micro-bumps.

16. The semiconductor device of claim 10, wherein the heat-dissipation chamber comprises:
a passivation layer on the channel structure; and
a connection layer on the substrate and in contact with the bump structure.

17. The semiconductor device of claim 16, wherein the connection layer comprises:
a lower connection layer in contact with the substrate; and
an upper connection layer between the lower connection layer and the side channel portion,
wherein the lower connection layer is a plate-shaped structure that extends along the top surface of the substrate, and
the upper connection layer is spaced apart from the bump structure and protrudes from the lower connection layer toward the side channel portion.

18. A semiconductor device, comprising:
a lower substrate;
an interposer substrate on the lower substrate;
a chip structure provided on the interposer substrate;
a heat-dissipation chamber adjacent to the chip structure; and
a heat spreader covering the heat-dissipation chamber, and the chip structure,
wherein the heat-dissipation chamber comprises:
a connection layer on the interposer substrate;
a bump structure including a plurality of micro-bumps on the connection layer, the plurality of micro-bumps being arranged to be spaced apart from each other along the interposer substrate; and
a channel structure on the connection layer,
wherein a chamber space enclosed by the connection layer and the channel structure is formed within the heat-dissipation chamber.

19. The semiconductor device of claim 18, wherein the channel structure comprises a side channel portion which extends in a third direction perpendicular to a top surface of the substrate, and an upper channel portion which covers an area surrounded by top portions of the side channel portion, and the heat-dissipation chamber comprises a plurality of penetration vias which penetrate the upper channel portion and extend into the chamber space.

20. The semiconductor device of claim 19, wherein a length of the chamber space is greater than a length of each of the penetration vias, when measured in a third direction perpendicular to the top surface of the substrate.
